(19) United States
(12) Patent Application Publication
(10) Pub. No.: US 2025/0211173 A1
(43) Pub. Date: Jun. 26, 2025

(54) POWER AMPLIFIER

(71) Applicant: INDUSTRIAL TECHNOLOGY RESEARCH INSTITUTE, Hsinchu (TW)

(72) Inventors: Sih-Han LI, New Taipei City (TW); Jie ZHANG, New Taipei City (TW); Peng-I MEI, Hualien County (TW); Chi-Hsiang HSU, Taoyuan City (TW)

(73) Assignee: INDUSTRIAL TECHNOLOGY RESEARCH INSTITUTE, Hsinchu (TW)

(21) Appl. No.: 18/396,300

(22) Filed: Dec. 26, 2023

(51) Int. Cl. H03F 1/02; H03F 3/21

(52) U.S. Cl. CPC H03F 1/0288; H03F 3/211; H03F 2200/222; H03F 2200/387

(57) ABSTRACT

A power amplifier includes a Doherty amplifier, and two input harmonic control circuits and two output harmonic control circuits configured to control harmonic resonance. The Doherty amplifier includes an input circuit, an output circuit, a main transistor and an auxiliary transistor arranged in parallel with the main transistor. A terminal of each one of the two input harmonic control circuits is connected to the input circuit, and another terminals of the two input harmonic control circuits are connected to input terminals of the main transistor and the auxiliary transistor, respectively. A terminal of each one of the two output harmonic control circuits is connected to the output circuit, and another terminal of each one of the two output harmonic control circuits is connected to an output terminal of the main transistor and the auxiliary transistor, respectively.

### TECHNICAL FIELD

This disclosure relates to a power amplifier.

### BACKGROUND

Among various power amplifier structures today, the Doherty amplifier is a common structure that can achieve high efficiency at optimum power back-off (OPBO). Moreover, in order to improve the operating efficiency of the power amplifier, a large number of passive components are used in the circuit design of the power amplifier.

### SUMMARY

According to an embodiment of this disclosure, a power amplifier includes a Doherty amplifier, two input harmonic control circuits and two output harmonic control circuits. The Doherty amplifier includes an input circuit, an output circuit, a main transistor and an auxiliary transistor arranged in parallel with the main transistor. A terminal of each of the two input harmonic control circuits is coupled to the input circuit, and another terminals of the two input harmonic control circuits are respectively coupled to input terminals of the main transistor and the auxiliary transistor. A terminal of each of the two output harmonic control circuits is coupled to the output circuit, and another terminals of the two output harmonic control circuits are respectively coupled to output terminals of the main transistor and the auxiliary transistor. The two input harmonic control circuits and the two output harmonic control circuits are configured to control harmonic resonance.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a block diagram illustrating a power amplifier according to an embodiment of the present disclosure;

FIG. 2 is a circuit diagram illustrating an input harmonic control circuit and an output harmonic control circuit at two terminals of a main transistor according to an embodiment of the present disclosure;

FIG. 3 is a circuit diagram illustrating an input harmonic control circuit and an output harmonic control circuit at two terminals of an auxiliary transistor according to an embodiment of the present disclosure;

FIG. 4 is a circuit diagram illustrating the main transistor according to an embodiment of the present disclosure;

FIG. 5 is a block diagram illustrating a power amplifier according to another embodiment of the present disclosure;

FIG. 6 is a circuit diagram illustrating an output circuit according to an embodiment of the present disclosure;

FIG. 7 is a schematic diagram illustrating an equivalent transformation according to an embodiment of the present disclosure;

FIG. 8 is a circuit diagram illustrating a power amplifier according to embodiments of the present disclosure;

FIG. 9 and FIG. 10 are graphs showing input power and output power of the power amplifier according to an embodiment of the present disclosure; and

FIG. 11 to FIG. 14 are Smith charts showing input power and output power of the main transistor and the auxiliary transistor respectively of the power amplifier according to an embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

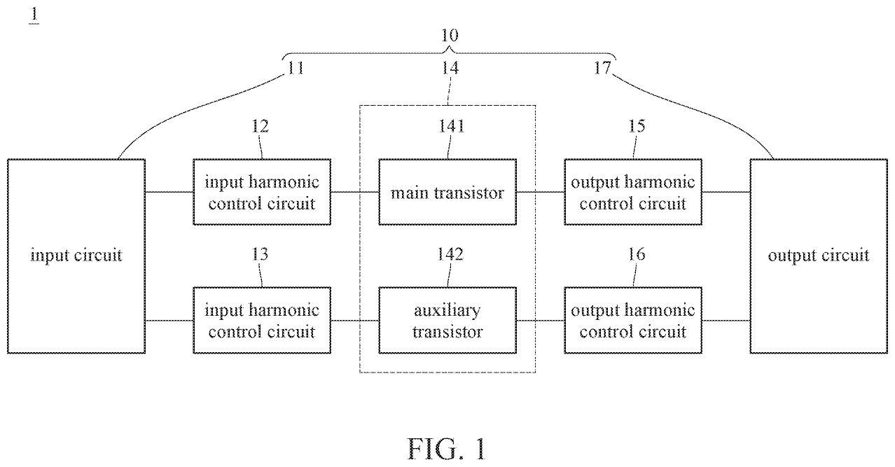

Please refer to FIG. 1, wherein FIG. 1 is a block diagram illustrating a power amplifier according to an embodiment of the present disclosure. As shown in FIG. 1, the power amplifier 1 may include a Doherty amplifier 10, two input harmonic control circuits 12 and 13 and two output harmonic control circuits 15 and 16. The Doherty amplifier 10 includes an input circuit 11, a transistor part 14 and an output circuit 17. The transistor part 14 may include a main transistor 141 and an auxiliary transistor 142 arranged in parallel.

A terminal of each of the input harmonic control circuits 12 and 13 is coupled to the input circuit 11, another terminal of the input harmonic control circuit 12 and another terminal of the input harmonic control circuit 13 are coupled to an input terminal of the main transistor 141 and an input terminal of the auxiliary transistor 142, respectively. A terminal of the output harmonic control circuit 15 and a terminal of the output harmonic control circuit 16 are coupled to an output terminal of the main transistor 141 and an output terminal of the auxiliary transistor 142, respectively, and another terminal of the output harmonic control circuit 15 and another terminal of the output harmonic control circuit 16 are coupled to the output circuit 17. Furthermore, the input terminal of each of the main transistor 141 and the auxiliary transistor 142 may be a gate of the transistor, and the output terminal of each of the main transistor 141 and the auxiliary transistor 142 may be a drain of the transistor.

In some embodiments, the input harmonic control circuit 12 and the input harmonic control circuit 13 may have a same circuit structure, the output harmonic control circuit 15 and the output harmonic control circuit 16 may have a same circuit structure, and the main transistor 141 and the auxiliary transistor 142 may have a same circuit structure.

The input harmonic control circuits 12 and 13 and the output harmonic control circuits 15 and 16 are configured to control harmonic resonance. Furthermore, the input harmonic control circuits 12 and 13 and the output harmonic control circuits 15 and 16 may be configured to control a parasitic capacitance integration based on the main transistor 141 and the auxiliary transistor 142 to operate at even harmonic frequencies or nearby harmonic frequencies of the frequency (fundamental frequency), such that internal voltages of the main transistor 141 and the auxiliary transistor 142 control source currents to flow to a reference plane. Therefore, low impedance may be effectively provided to a signal at even harmonic frequencies, for example, low impedance may be provided to a signal at the second harmonic frequency. The reference plane may be an input side or an output side of a dependent current source of a transistor. The input harmonic control circuits 12 and 13 and the output harmonic control circuits 15 and 16 may be further configured to control a parasitic capacitance integration based on the main transistor 141 and the auxiliary transistor 142 to operate at odd harmonic frequencies or nearby harmonic frequencies of the frequency (fundamental frequency), such that internal voltages of the main transistor 141 and the auxiliary transistor 142 control source currents to flow to reference plane. Therefore, low impedance may be effectively provided to a signal at the odd harmonic frequencies, for example, low impedance may be provided to a signal at the third harmonic frequency. According to the structure of the power amplifier described above, the amplification efficiency of the power amplifier may be effectively improved. Through disposing the input harmonic control circuit and the output harmonic control circuit, the effect that the signal at the second harmonic frequency approaches the load impedance of a short circuit and the signal at the third harmonic frequency approaches the load impedance of an open circuit may be achieved.

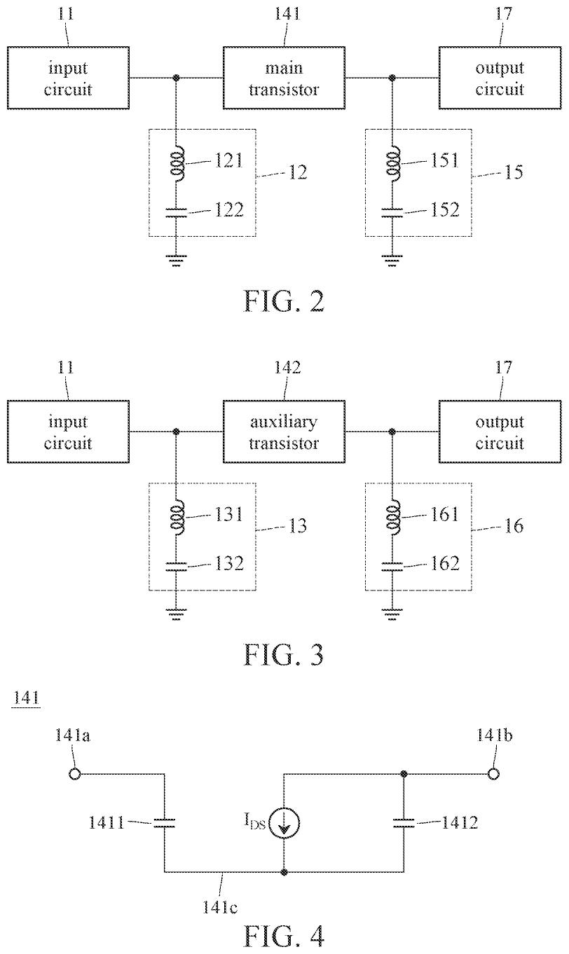

Please refer to FIG. 1 and FIG. 2, wherein FIG. 2 is a circuit diagram illustrating an input harmonic control circuit and an output harmonic control circuit at two terminals of a main transistor according to an embodiment of the present disclosure. As shown in FIG. 2, the input harmonic control circuit 12 may include a harmonic control inductive element 121 and a harmonic control capacitive element 122. The harmonic control capacitive element 122 is coupled in series with the harmonic control inductive element 121. Furthermore, a terminal of the harmonic control inductive element 121 is coupled to an output terminal of the input circuit 11 and an input terminal of the main transistor 141, another terminal of the harmonic control inductive element 121 is coupled to a terminal of the harmonic control capacitive element 122, and another terminal of the harmonic control capacitive element 122 is grounded.

The output harmonic control circuit 15 may include a harmonic control inductive element 151 and a harmonic control capacitive element 152. The harmonic control capacitive element 152 is coupled in series with the harmonic control inductive element 151.

Furthermore, a terminal of the harmonic control inductive element 151 is coupled to an output terminal of the main transistor 141 and an input terminal of the output circuit 17, another terminal of the harmonic control inductive element 151 is coupled to a terminal of the harmonic control capacitive element 152, and another terminal of the harmonic control capacitive element 152 is grounded.

Please refer to FIG. 1 and FIG. 3, wherein FIG. 3 is a circuit diagram illustrating an input harmonic control circuit and an output harmonic control circuit at two terminals of an auxiliary transistor according to an embodiment of the present disclosure. As shown in FIG. 3, the input harmonic control circuit 13 may include a harmonic control inductive element 131 and a harmonic control capacitive element 132. The harmonic control capacitive element 132 is coupled in series with the harmonic control inductive element 131. Furthermore, a terminal of the harmonic control inductive element 131 is coupled to the output terminal of the input circuit 11 and the input terminal of the auxiliary transistor 142, another terminal of the harmonic control inductive element 131 is coupled to a terminal of the harmonic control capacitive element 132, and another terminal of the harmonic control capacitive element 132 is grounded.

The output harmonic control circuit 16 may include a harmonic control inductive element 161 and a harmonic control capacitive element 162. The harmonic control capacitive element 162 is coupled in series with the harmonic control inductive element 161.

Furthermore, a terminal of the harmonic control inductive element 161 is coupled to the output terminal of the auxiliary transistor 142 and the input terminal of the output circuit 17, another terminal of the harmonic control inductive element 161 is coupled to a terminal of the harmonic control capacitive element 162, and another terminal of the harmonic control capacitive element 162 is grounded.

Please refer to FIG. 1, FIG. 2 and FIG. 3. An inductance value of the harmonic control inductive element 121 and a capacitance value of the harmonic control capacitive element 122 of the input harmonic control circuit 12 are associated with a capacitance value of gate-source parasitic capacitance of the main transistor 141, and an inductance value of the harmonic control inductive element 131 and a capacitance value of the harmonic control capacitive element 132 of the input harmonic control circuit 13 are associated with a capacitance value of gate-source parasitic capacitance of the auxiliary transistor 142. In some embodiments, said “associated with” may indicate having negative association. In addition, the inductance value of the harmonic control inductive element 121 of the input harmonic control circuit 12 is further negatively associated with an operating frequency of the main transistor 141, and the inductance value of the harmonic control inductive element 131 of the input harmonic control circuit 13 is further negatively associated with an operating frequency of the auxiliary transistor 142.

In some embodiments, the inductance values of the harmonic control inductive elements 121 and 131 and the capacitance values of the harmonic control capacitive elements 122 and 132 of the input harmonic control circuits 12 and 13 may be represented by equation (1) and equation (2) below, respectively, wherein L_{IHC} is the inductance value of the harmonic control inductive element; C_{IHC} is the capacitance value of the harmonic control capacitive element; ω₀ is an operating frequency of the transistor; C_{GS} is the capacitance value of the gate-source parasitic capacitance. Further, for the input harmonic control circuit 12, ω₀ is the operating frequency of the main transistor 141, and C_{GS} is the capacitance value of the gate-source parasitic capacitance of the main transistor 141; and for the input harmonic control circuit 13, ω₀ is the operating frequency of the auxiliary transistor 142, and C_{GS} is the capacitance value of the gate-source parasitic capacitance of the auxiliary transistor 142.

$${L}_{IHC} = \frac{1}{5 {ω}_{0}^{2} {C}_{GS}} \qquad equation ( 1 )$$

$${C}_{IHC} = \frac{5}{4 {C}_{GS}} \qquad equation ( 2 )$$

The inductance value of the harmonic control inductive element 151 and the capacitance value of the harmonic control capacitive element 152 of the output harmonic control circuit 15 are associated with a capacitance value of a drain-source parasitic capacitance of the main transistor 141, and the inductance value of the harmonic control inductive element 161 and the capacitance value of the harmonic control capacitive element 162 of the output harmonic control circuit 16 are associated with the capacitance value of the drain-source parasitic capacitance of the auxiliary transistor 142. In some embodiments, said “associated with” may indicate having negative association. In addition, the inductance value of the harmonic control inductive element 151 of the output harmonic control circuit 15 is further negatively associated with the operating frequency of the main transistor 141, and the inductance value of the harmonic control inductive element 161 of the output harmonic control circuit 16 is further negatively associated with the operating frequency of the auxiliary transistor 142.

The inductance values of the harmonic control inductive elements 151 and 161 and the capacitance values of the harmonic control capacitive elements 152 and 162 of the output harmonic control circuits 15 and 16 may be represented by equation (3) and equation (4) below, respectively, wherein L_{OHC} is the inductance value of the harmonic control inductive element; C_{OHC} is the capacitance value of the harmonic control capacitive element; ω₀ is an operating frequency of the transistor; C_{DS} is the capacitance value of the drain-source parasitic capacitance. Furthermore, for the output harmonic control circuit 15, ω₀ is the operating frequency of the main transistor 141, and C_{DS} is the capacitance value of the drain-source parasitic capacitance of the main transistor 141; and for the output harmonic control circuit 16, ω₀ is the operating frequency of the auxiliary transistor 142, and C_{DS} is the capacitance value of the drain-source parasitic capacitance of the auxiliary transistor 142.

$${L}_{OHC} = \frac{1}{5 {ω}_{0}^{2} {C}_{DS}} \qquad equation ( 3 )$$

$${C}_{OHC} = \frac{5}{4 {C}_{DS}} \qquad equation ( 4 )$$

Please refer to FIG. 1 and FIG. 4, wherein FIG. 4 is a circuit diagram illustrating the main transistor according to an embodiment of the present disclosure. As shown in FIG. 4, the main transistor 141 includes a gate 141a, a drain 141b and a source 141c. The gate 141a of the main transistor 141 is connected to an output terminal of the input harmonic control circuit 12, the drain 141b of the main transistor 141 is connected to an input terminal of the output harmonic control circuit 15, and the source 141c of the main transistor 141 is grounded. More specifically, the gate-source parasitic capacitance 1411 may be formed between the gate 141a and the source 141c, and the drain-source capacitance capacitor 1412 may be formed between the drain 141b and the source 141c. The drain 141b may output a current I_{DS} to the source 141c.

A method of calculating the capacitance value of the gate-source parasitic capacitance 1411 may be using equation (5) shown below, and a method of calculating the capacitance value of the drain-source parasitic capacitance 1412 may be using equation (6) shown below, wherein Y₁₁, Y₁₂ and Y₂₂ are admittance parameters of the circuit shown in FIG. 4; C_{GS} is the capacitance value of the gate-source parasitic capacitance 1411, and may be the C_{GS} in equation (1) and equation (2); C_{DS} is the capacitance value of the drain-source parasitic capacitance 1412, and may be the C_{DS} in equation (3) and equation (4).

$${C}_{GS} \approx \frac{[ Im ( {Y}_{11} ) + Im ( {Y}_{12} ) ]}{{ω}_{0}} \{ 1 + \frac{{[ Re ( {Y}_{11} ) + Re ( {Y}_{12} ) ]}^{2}}{{[ Im ( {Y}_{11} ) + Im ( {Y}_{12} ) ]}^{2}} \} \qquad equation ( 5 )$$

$${C}_{DS} = \frac{Im ( {Y}_{DS} )}{{ω}_{0}} = \frac{Im ( {Y}_{22} ) + Im ( {Y}_{12} )}{{ω}_{0}} \qquad equation ( 6 )$$

The structure of the auxiliary transistor 142 and the method of calculating the capacitance value of the parasitic capacitance of the auxiliary transistor 142 are the same as that of the main transistor 141, their descriptions are not repeated herein.

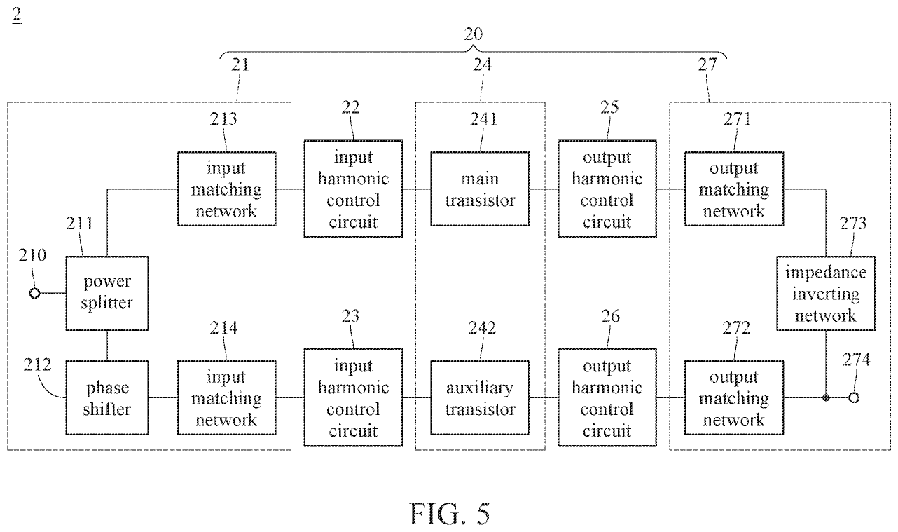

Please refer to FIG. 5, wherein FIG. 5 is a block diagram illustrating a power amplifier according to another embodiment of the present disclosure. As shown in FIG. 5, the power amplifier 2 includes a Doherty amplifier 20, two input harmonic control circuits 22 and 23 and two output harmonic control circuits 25 and 26. The Doherty amplifier 20 includes an input circuit 21, a transistor part 24 and an output circuit 27. The transistor part 24 includes a main transistor 241 and an auxiliary transistor 242 arranged parallel with each other. More specifically, the implementations of the input harmonic control circuit 22 and 23, the transistor part 24 and the output harmonic control circuits 25 and 26 may be the same as that of the input harmonic control circuits 12 and 13, the transistor part 14 and the output harmonic control circuits 15 and 16 described above, their descriptions are not repeated herein.

In some embodiments, the input circuit 21 may include an input terminal 210, a power splitter 211, a phase shifter 212 and two input matching networks 213 and 214. More specifically, an input terminal of the power splitter 211 may be coupled to the input terminal 210 of the power amplifier 2. The input matching network 213 is coupled between the power splitter 211 and the input harmonic control circuit 22, and the input matching network 214 is coupled between the phase shifter 212 and the input harmonic control circuit 23.

The power splitter 211 may be configured to equally distribute input power from the input terminal 210 to the main transistor 241 and the auxiliary transistor 242. The phase shifter 212 may be configured to compensate a phase difference between outputs of the main transistor 241 and the auxiliary transistor 242. The input matching networks 213 and 214 may be configured to minimize a signal reflection of the input terminal 210.

In some embodiments, the output circuit 27 may include two output matching networks 271 and 272, an impedance inverting network 273 and an output terminal 274. More specifically, the output matching network 271 is coupled between the output harmonic control circuit 25 and the impedance inverting network 273, and the output matching network 272 is coupled between the output harmonic control circuit 26 and the impedance inverting network 273. The output matching network 272 and the impedance inverting network 273 are further coupled to the output terminal 274.

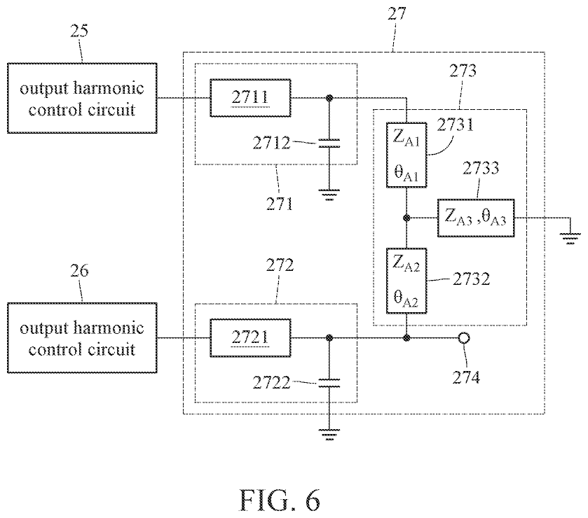

Please refer to FIG. 5 and FIG. 6, wherein FIG. 6 is a circuit diagram illustrating an output circuit according to an embodiment of the present disclosure. As shown in FIG. 6, the output circuit 27 includes the two output matching networks 271 and 272, the impedance inverting network 273 and the output terminal 274. More specifically, the output matching network 271 may include a first output matching network transmission line 2711 and a first matching capacitor 2712. The first output matching network transmission line 2711 is coupled between the output harmonic control circuit 25 and a terminal of the first matching capacitor 2712, and another terminal of the first matching capacitor 2712 is grounded. The output matching network 272 may include a second output matching network transmission line 2721 and a second matching capacitor 2722. The second output matching network transmission line 2721 is coupled between the output harmonic control circuit 26 and a terminal of the second matching capacitor 2722, and another terminal of the second matching capacitor 2722 is grounded.

In some embodiments, the impedance inverting network 273 may include a first transmission line 2731, a second transmission line 2732 and a third transmission line 2733. A terminal of the first transmission line 2731 is coupled to the first matching capacitor 2712 and the first output matching network transmission line 2711, another terminal of the first transmission line 2731 is coupled to a terminal of the second transmission line 2732 and a terminal of the third transmission line 2733. Another terminal of the second transmission line 2732 is coupled to the second output matching network transmission line 2721 and the second matching capacitor 2722, and another terminal of the third transmission line 2733 is grounded. Said another terminal of the second transmission line 2732 is further coupled to the output terminal 274. The grounded terminal of the third transmission line 2733 may further act as a feed-in terminal of a drain direct current supply voltage of the main transistor 241 and the auxiliary transistor 242.

In some embodiments, the capacitance value of the first matching capacitor 2712, the capacitance value of the second matching capacitor 2722 as well as an impedance and a phase of each of the first transmission line 2731, the second transmission line 2732 and the third transmission line 2733 are obtained by performing an equivalent transformation on two matching inductors of the two output matching networks 271 and 272 of the output circuit 27 and a single transmission line. In some embodiments, the equivalent transformation may include one or more π model equivalent circuit transformations and/or one or more wye-delta equivalent transformations. More specifically, the first transmission line 2731, the second transmission line 2732 and the third transmission line 2733 are equivalently transformed into a single transmission line with a shorter length by the equivalent transformations, thereby effectively reducing an overall occupied area of the power amplifier.

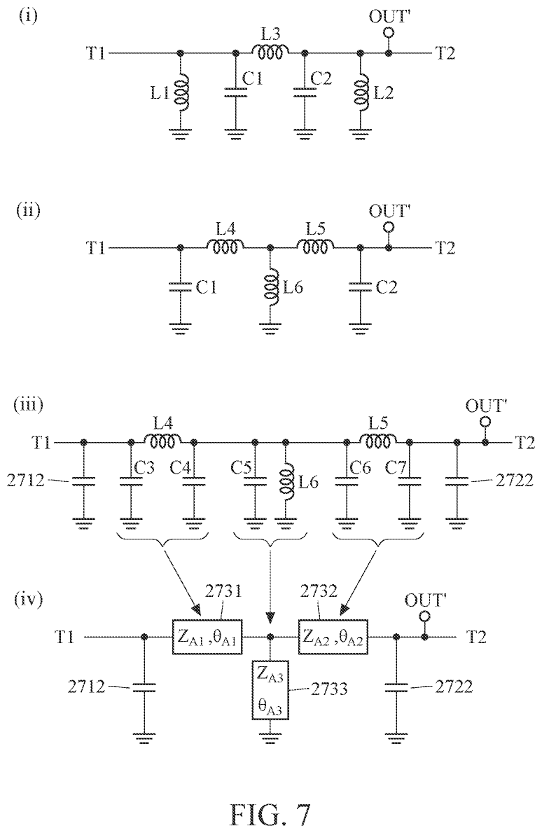

FIG. 7 is a schematic diagram illustrating an equivalent transformation according to an embodiment of the present disclosure, wherein FIG. 7 shows performing the equivalent transformation on the impedance inverting network 273 with a characteristic impedance of 100 ohms and a phase of 90 degrees. It should be noted that terminals T1 and T2 shown in FIG. 7 may be connected to the output terminals of the output harmonic control circuits 25 and 26 shown in FIG. 5, respectively, and an output terminal OUT′ may be the output terminal 274 shown in FIG. 5. Furthermore, the terminals T1 and T2 may be connected to the first output matching network transmission line 2711 of the output matching network 271 and the second output matching network transmission line 2721 of the output matching network 272, respectively. More specifically, a first inductor L1 and a second inductor L2 shown in FIG. 7 may be matching inductors of the two output matching networks 271 and 272 of the output circuit 27, respectively, and the first inductor L1, the second inductor L2 and the impedance inverting network 273 may be transformed into a single transmission line between the terminals T1 and T2.

First, in stage (i), the single transmission line between the terminals T1 and T2 are equivalently transformed into a π model according to equation (7) and equation (8), wherein L is a third inductor L3 of the impedance inverting network 273, C is a first capacitor C1 and a second capacitor C2 of the impedance inverting network 273, d2 is the phase (90 degrees), C2 is the characteristic impedance (100 ohms), and B2 is a value of π square multiplied by 2 (2(π²)).

$$L = \frac{sin ( rad ( d 2 ) ) \times C 2}{B 2} \qquad equation ( 7 )$$

$$C = \frac{tan ( rad ( \frac{d 2}{2} ) )}{B 2 \times C 2} \qquad equation ( 8 )$$

In this embodiment, the π model includes the first capacitor C1, the second capacitor C2 and the third inductor L3. In some embodiments, the capacitance value of the first capacitor C1 is the same as the capacitance value of the second capacitor C2. More specifically, a terminal of the first capacitor C1 is connected to a terminal of the first inductor L1 and a terminal of the third inductor L3. A terminal of the second capacitor C2 is connected to a terminal of the second inductor L2 and another terminal of the third inductor L3. Another terminal of the first capacitor C1 and another terminal of the second capacitor C2 are grounded.

Then, in stage (ii), the π model is equivalently transformed into a wye-delta model according to equation (9), equation (10) and equation (11), wherein the wye-delta model includes a fourth inductor L4, a fifth inductor L5 and a sixth inductor L6.

$$L 4 = \frac{L 1 \times L 3}{L 1 + L 2 + L 3} \qquad equation ( 9 )$$

$$L 5 = \frac{L 2 \times L 3}{L 1 + L 2 + L 3} \qquad equation ( 10 )$$

$$L 6 = \frac{L 2 \times L 3}{L 1 + L 2 + L 3} \qquad equation ( 11 )$$

Two terminals of the fourth inductor L4 are connected to the terminal of the first capacitor C1 that is not grounded, a terminal of the fifth inductor L5 and a terminal of the sixth inductor L6. Another terminal of the fifth inductor L5 is connected to the terminal of the second capacitor C2 that is not grounded. Another terminal of the sixth inductor L6 is grounded.

Furthermore, the present disclosure may be designed and adjusted according to actual needs. For example, in stage (iii) of the present embodiment, the first capacitor C1 of stage (ii) may be divided into the first matching capacitor 2712 and a third capacitor C3; the second capacitor C1 of stage (ii) may be divided into the second matching capacitor 2722 and a seventh capacitor C7; the sixth inductor L6 of stage (ii) may be adjusted into another inductor, a fourth capacitor C4, a fifth capacitor C5 and a sixth capacitor C6, wherein the capacitance value of the third capacitor C3 and the capacitance value of the fourth capacitor C4 are equal to each other, and the capacitance value of the sixth capacitor C6 and the capacitance value of the seventh capacitor C7 are equal to each other. In other words, the first capacitor C1 and the second capacitor C2 are equivalently transformed into three π models added with multiple capacitors. The first π model includes the third capacitor C3, the fourth capacitor C4 and the fourth inductor L4, the second π model includes the sixth capacitor C6, the seventh capacitor C7 and the fifth inductor L5, and the third π model includes the fifth capacitor C5, the sixth inductor L6 and a grounded terminal. More specifically, the added capacitors include the first matching capacitor 2712 and the second matching capacitor 2722. At this time, after the design and adjustment of stage (iii), the line width of the transformed transmission line may satisfy the current density requirement during application.

A terminal of the third capacitor C3 and a terminal of the first matching capacitor 2712 are connected to a terminal of the fourth inductor L4, and another terminal of the third capacitor C3 and another terminal of the first matching capacitor 2712 are grounded. A terminal of each of the fourth capacitor C4, the fifth capacitor C5, the fifth inductor L5, the sixth inductor L6 and the sixth capacitor C6 is connected to another terminal of the fourth inductor L4. Another terminal of each of the fourth capacitor C4, the fifth capacitor C5, the sixth inductor L6 and the sixth capacitor C6 that is not connected to the fourth inductor L4 is grounded. A terminal of each of the seventh capacitor C7 and the second matching capacitor 2722 is connected to another terminal of the fifth inductor L5, and another terminal of each of the seventh capacitor C7 and the second matching capacitor 2722 is grounded.

Lastly, in stage (iv), the first π model, the second Tt model and the third π model are transformed into the first transmission line 2731, the second transmission line 2732 and the third transmission line 2733. Specifically, according to equation (12) and equation (13), the fourth inductor L4, the third capacitor C3 and the fourth capacitor C4 are equivalently transformed into the first transmission line 2731. The fifth inductor L4, the sixth capacitor C6 and the seventh capacitor C7 are equivalently transformed into the second transmission line 2732. The fifth capacitor C5 and the sixth inductor L6 are equivalently transformed into the third transmission line 2733. In equation (12) and equation (13), Z₀ is the characteristic impedance of the transmission line, θ is the phase of the transmission line, B2 is a value of π square multiplied by 2 and the fundamental operating frequency (2×fundamental operating frequency×π²), E2 is the inductance value of the inductor, and F2 is the capacitance value of the capacitor.

$${Z}_{0} = \sqrt{\frac{E 2}{F 2 \times ( 2 - B {2}^{2} \times E 2 \times F 2 )}} \qquad equation ( 12 )$$

$$θ = {cos}^{- 1} ( 1 - B {2}^{2} \times E 2 \times F 2 ) \qquad equation ( 13 )$$

Specifically, for the first transmission line 2731, in equation (12) and equation (13), E2 is the inductance value of the fourth inductor L4, F2 is the capacitance value of the third capacitor C3/the fourth capacitor C4; and for the second transmission line 2732, in equation (12) and equation (13), E2 is the inductance value of the fifth inductor L5, F2 is the capacitance value of the sixth capacitor C6/the seventh capacitor C7; for the third transmission line 2733, in equation (12) and equation (13), E2 is the inductance value of the sixth inductor L6, F2 is the capacitance value of the fifth capacitor C5.

In some embodiments, a total length of the first transmission line 2731, the second transmission line 2732 and the third transmission line 2733 obtained by the equivalent transformation may be smaller than a length of the single transmission line between the terminals T1 and T2. For example, the original length of the single transmission line between the terminals T1 and T2 is 4900 micrometers (um), and the total length of the first transmission line 2731, the second transmission line 2732 and the third transmission line 2733 obtained by the equivalent transformation may be reduced to 1790 micrometers (um), but the present disclosure is not limited to these lengths. At the same time, an occupied area of the first transmission line 2731, the second transmission line 2732 and the third transmission line 2733 after the equivalent transformation may be smaller than an occupied area of the single transmission line between the terminals T1 and T2. In view of the above, by the equivalent transformation of the present disclosure, after the equivalent transformation, the length of the transmission line may be reduced, thereby reducing an overall area of the power amplifier.

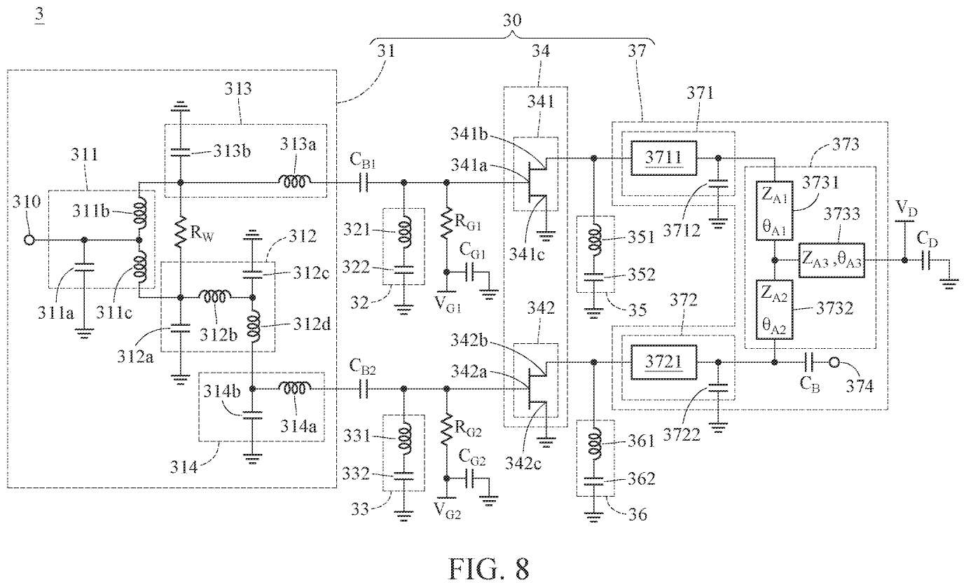

Please refer to FIG. 8, wherein FIG. 8 is a circuit diagram illustrating a power amplifier according to embodiments of the present disclosure. As shown in FIG. 8, the power amplifier 3 includes a Doherty amplifier 30, two input harmonic control circuits 32 and 33 and two output harmonic control circuits 35 and 36. The Doherty amplifier 30 includes an input circuit 31, a transistor part 34 and an output circuit 37.

More specifically, the input circuit 31 includes an input terminal 310, a power splitter 311, a phase shifter 312 and two input matching networks 313 and 314. In some embodiments, the power splitter 311 may include a capacitor 311a and inductors 311b and 311c. A terminal of the capacitor 311a is grounded, another terminal of the capacitor 311a is coupled between the inductor 311b and the inductor 311c. Another terminal of the inductor 311b is coupled to the input matching networks 313, and another terminal of the inductor 311c is coupled to the phase shifter 312.

In some embodiments, the phase shifter 312 may include capacitors 312a and 312c and inductors 312b and 312d. A terminal of the capacitor 312a is coupled between the inductor 311c and the inductor 312b of the power splitter 311, and another terminal of the capacitor 312a is grounded. The inductor 312b is coupled between the inductor 311c and a terminal of the capacitor 312c. Another terminal of the capacitor 312c is grounded. A terminal of the inductor 312d is coupled to the inductor 312b and the capacitor 312c, and another terminal of the inductor 312d is coupled to the input matching networks 314.

In some embodiments, the input matching network 313 may include an inductor 313a and a capacitor 313b. A terminal of the inductor 313a is coupled to a terminal of the capacitor 313b, and another terminal of the inductor 313a is coupled to the input harmonic control circuit 32. Another terminal of the capacitor 313b is grounded. In addition, the input matching network 314 may also include an inductor 314a and a capacitor 314b. A terminal of the inductor 314a is coupled to a terminal of the capacitor 314b, and another terminal of the inductor 314a is coupled to the input harmonic control circuit 33. Another terminal of the capacitor 314b is grounded. In short, the input matching network 313 and the input matching network 314 have a same circuit structure.

In some embodiments, the input harmonic control circuit 32 may include a harmonic control inductive element 321 and a harmonic control capacitive element 322, and the input harmonic control circuit 33 may include a harmonic control inductive element 331 and a harmonic control capacitive element 332. More specifically, the structures of the input harmonic control circuits 32 and 33 may be the same as the input harmonic control circuit described with reference with FIG. 2, their descriptions are not repeated herein.

In some embodiments, the transistor part 34 includes a main transistor 341 and an auxiliary transistor 342 arranged in parallel with each other. The gate 341a of the main transistor 341 of the transistor part 34 is coupled to the harmonic control inductive element 321 of the input harmonic control circuit 32, the drain 341b of the main transistor 341 of the transistor part 34 is coupled to the output harmonic control circuit 35, and the source 341c of the main transistor 341 is grounded. In addition, the gate 342a of the auxiliary transistor 342 of the transistor part 34 is coupled to the harmonic control inductive element 331 of the input harmonic control circuit 33, the drain 342b of the auxiliary transistor 342 is coupled to the output harmonic control circuit 36, and the source 342c of the auxiliary transistor 342 is grounded. More specifically, the structures of the main transistor 341 and the auxiliary transistor 342 may be the same as the main transistor and the auxiliary transistor described with reference with FIG. 4, their descriptions are not repeated herein.

In some embodiments, the output harmonic control circuit 35 may include the harmonic control inductive element 351 and the harmonic control capacitive element 352, and the output harmonic control circuit 36 may include the harmonic control inductive element 361 and the harmonic control capacitive element 362. More specifically, the structures of the output harmonic control circuits 35 and 36 may be the same as the output harmonic control circuits described with reference with FIG. 3, their descriptions are not repeated herein.

More specifically, the output circuit 37 includes two input matching networks 371 and 372, an impedance inverting network 373 and an output terminal 374. In some embodiments, the output matching network 371 may include the first output matching network transmission line 3711 and the first matching capacitor 3712. The output matching network 372 may include the second output matching network transmission line 3721 and the second matching capacitor 3722. The structures of the output matching networks 371 and 372 may be the same as the output matching networks 271 and 272 described with reference with FIG. 6, their descriptions are not repeated herein. The impedance inverting network 373 includes the first transmission line 3731, the second transmission line 3732 and the third transmission line 3733. More specifically, the impedance inverting network 373 may be the impedance inverting network described with reference with FIG. 6 and FIG. 7, their descriptions are not repeated herein.

In addition, the power amplifier 3 may further include capacitors C_{B}, C_{B1}, C_{B2}, C_{D}, resistors R_{W}, R_{G1}, R_{G2}, and capacitors C_{G1}, C_{G2}. In some embodiments, the capacitor C_{B} may be coupled between the second transmission line 3734 and the output terminal OUT. The capacitor C_{B1} may be coupled between the input matching network 313 and the input harmonic control circuit 32. The capacitor C_{B2} may be coupled between the input matching network 314 and the input harmonic control circuit 33. The capacitor C_{D} may be coupled between the third transmission line 3733 and a grounded terminal. The capacitor C_{D} may be coupled to the terminal of the third transmission line 3733, and may be further connected to a drain voltage source V_{D}.

In some embodiments, a terminal of the resistor R_{W} may be coupled to the input matching network 313, and another terminal of the resistor R_{W} is coupled to the phase shifter 312. A terminal of the resistor R_{G1} may be coupled between the input harmonic control circuit 32 and the gate 341a of the main transistor 341, and another terminal of the resistor R_{G1} may be coupled to a terminal of the capacitor C_{G1} and a gate voltage source V_{G1}. Another terminal of the capacitor C_{G1} is grounded. A terminal of the resistor R_{G2} may be coupled between the input harmonic control circuit 33 and the gate 342a of the auxiliary transistor 342, and another terminal of the resistor R_{G2} may be coupled to a terminal of the capacitor C_{G2} and a gate voltage source V_{G2}. Another terminal of the capacitor C_{G2} is grounded.

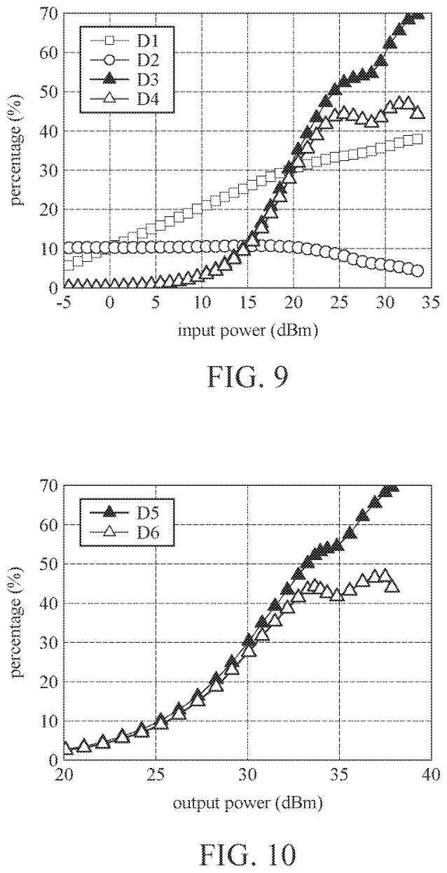

Please refer to FIG. 9 and FIG. 10, wherein FIG. 9 and FIG. 10 are graphs showing input power and output power of the power amplifier according to an embodiment of the present disclosure. As shown in FIG. 9, the horizontal axis represents the input power of the power amplifier, and the unit is decibel relative to one milliwatt (dBm); the vertical axis corresponds to different curves D1, D2, D3, D4, wherein curve D1 represents the output power of the power amplifier, and the unit is decibel relative to one milliwatt (dBm); curve D2 represents the gain of the power amplifier, and the unit is decibel (dB); curve D3 represents the drain efficiency, and the unit is percentage (%); curve D4 represents the power-added efficiency (PAE), and the unit is percentage (%). As shown in FIG. 10, the horizontal axis represents the output power of the power amplifier, and the unit is decibel relative to one milliwatt (dBm); the vertical axis corresponds to different curves D5, D6, wherein curve D5 represents the drain efficiency, and the unit is percentage (%); curve D6 represents the power-added efficiency (PAE), and the unit is percentage (%). It can be seen from FIG. 9 and FIG. 10 that even if the input power is low, the power amplifier according to one or more embodiments of the present disclosure may still have high efficiency performance.

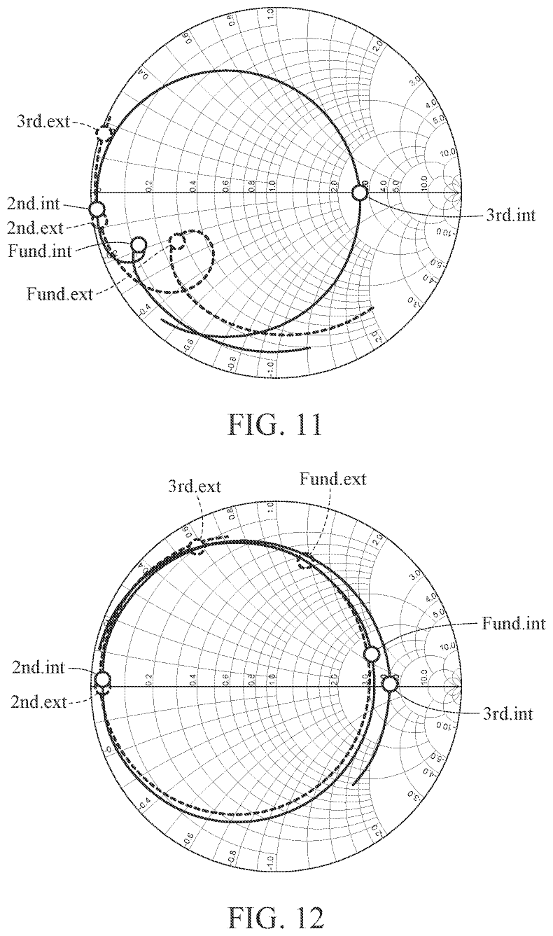

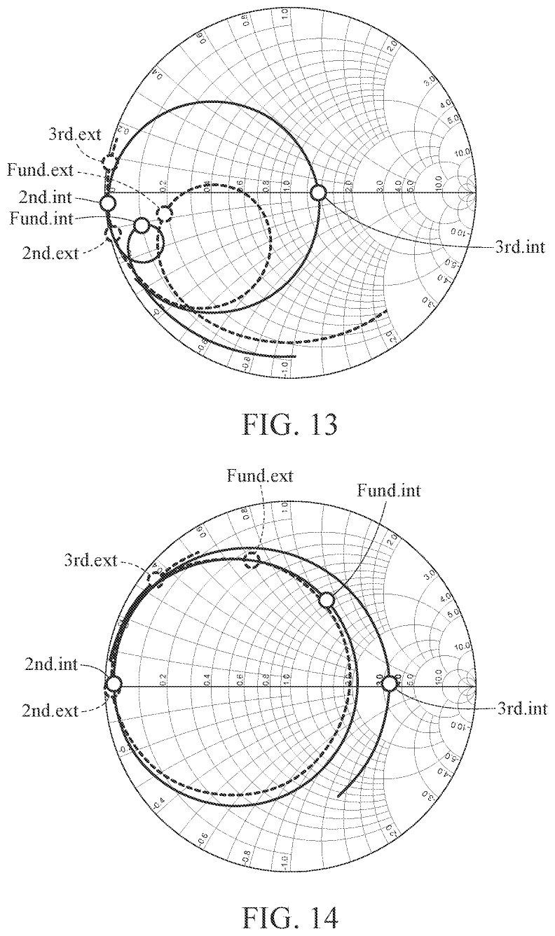

Please refer to FIG. 11 to FIG. 14, wherein FIG. 11 to FIG. 14 are Smith charts showing input power and output power of the main transistor and the auxiliary transistor respectively of the power amplifier according to an embodiment of the present disclosure. FIG. 11 and FIG. 12 show the Smith charts of an input and an output of the main transistor, respectively, and FIG. 13 and FIG. 14 show the Smith charts of an input and an output of the auxiliary transistor, respectively. As shown in FIG. 11 to FIG. 14, the power amplifier according to one or more embodiments of the present disclosure may realize the load impedance at which signals near the second harmonic frequency approaching a short circuit and the load impedance at which signals near the third harmonic frequency approaching an open circuit. In FIG. 11 to FIG. 14, the leftmost side of the Smith chart is 0 impedance, and the rightmost side of the Smith chart is infinite impedance. The impedance value Fund.int represents the impedance value at the fundamental frequency of the frequency point operation obtained by taking the input side or the output side of the dependent current source of the transistor as the reference plane; the impedance value Fund.ext represents the impedance value at the fundamental frequency of the frequency point operation obtained by taking the terminal of the gate (for inputting the Smith chart) or the drain (for outputting the Smith chart) of the transistor as the reference plane; the impedance value 2nd.int represents the impedance value at the second harmonic frequency of the frequency point obtained by taking the input side or the output side of the dependent current source of the transistor as the reference plane; the impedance value 2nd.ext represents the impedance value at the second harmonic frequency of the frequency point obtained by taking the terminal of the gat or the drain of the transistor as the reference plane; the impedance value 3rd.in represents the impedance value at the third harmonic frequency of the frequency point obtained by taking the input side or the output side of the dependent current source of the transistor as the reference plane; and the impedance value 3nd.ext represents the impedance value at the third harmonic frequency of the frequency point obtained by taking the terminal of the gat or the drain of the transistor as the reference plane. As shown in FIGS. 11 to 14, the power amplifier of the present disclosure may have low impedance at second harmonic frequency and high impedance at third harmonic frequency.

In view of the above description, the power amplifier according to one or more embodiments of the present disclosure may effectively improve the amplification efficiency of the power amplifier. By disposing the harmonic control circuits, the effect that the signal at the second harmonic frequency approaches the load impedance of a short circuit, and the signal at the third harmonic frequency approaches the load impedance of an open circuit may be achieved. In addition, the power amplifier according to one or more embodiments of the present disclosure may have lower overall area by the equivalent transformation operation of the impedance inverting network.

What is claimed is:

1. A power amplifier, comprising:
a Doherty amplifier, comprising:
an input circuit;
an output circuit;
a main transistor; and
an auxiliary transistor arranged in parallel with the main transistor;
two input harmonic control circuits, wherein a terminal of each of the two input harmonic control circuits is coupled to the input circuit, and another terminals of each of the two input harmonic control circuits are respectively coupled to input terminals of the main transistor and the auxiliary transistor; and
two output harmonic control circuits, wherein a terminal of each of the two output harmonic control circuits is coupled to the output circuit, and another terminals of each of the two output harmonic control circuits are respectively coupled to output terminals of the main transistor and the auxiliary transistor, wherein the two input harmonic control circuits and the two output harmonic control circuits are configured to control harmonic resonance.

2. The power amplifier according to claim 1, wherein the two input harmonic control circuits and the two output harmonic control circuits are configured to control even harmonic frequencies based on operating frequencies of the main transistor and the auxiliary transistor, respectively.

3. The power amplifier according to claim 2, wherein the two input harmonic control circuits and the two output harmonic control circuits are configured to control operating frequencies based on the main transistor and the auxiliary transistor, respectively, to provide low impedance at the even harmonic frequencies.

4. The power amplifier according to claim 3, wherein the two input harmonic control circuits and the two output harmonic control circuits are configured to control the operating frequencies based on the main transistor and the auxiliary transistor, respectively, to provide low impedance at the second harmonic frequency.

5. The power amplifier according to claim 1, wherein the two input harmonic control circuits and the two output harmonic control circuits are configured to control odd harmonic frequencies based on operating frequencies of the main transistor and the auxiliary transistor, respectively.

6. The power amplifier according to claim 5, wherein the two input harmonic control circuits and the two output harmonic control circuits are configured to control operating frequencies based on the main transistor and the auxiliary transistor, respectively, to provide high impedance at the odd harmonic frequencies.

7. The power amplifier according to claim 6, wherein the two input harmonic control circuits and the two output harmonic control circuits are configured to control the operating frequencies based on the main transistor and the auxiliary transistor, respectively, to provide high impedance at the third harmonic frequency.

8. The power amplifier according to claim 1, wherein each one of the two input harmonic control circuits and the two output harmonic control circuits comprises:
a harmonic control inductive element; and
a harmonic control capacitive element coupled in series with the harmonic control inductive element.

9. The power amplifier according to claim 8, wherein an inductance value of the harmonic control inductive element and a capacitance value of the harmonic control capacitive element of each of the two input harmonic control circuits are associated with a capacitance value of a gate-source parasitic capacitance of each of the main transistor and the auxiliary transistor, respectively; and
an inductance value of the harmonic control inductive element and a capacitance value of the harmonic control capacitive element of each of the two output harmonic control circuits are associated with a capacitance value of a drain-source parasitic capacitance of each of the main transistor and the auxiliary transistor, respectively.

10. The power amplifier according to claim 9, wherein the inductance value of the harmonic control inductive element of each of the two input harmonic control circuits is further negatively associated with operating frequencies of the main transistor and the auxiliary transistor, respectively, and the inductance value of the harmonic control inductive element of each of the two output harmonic control circuits is further negatively associated with operating frequencies of the main transistor and the auxiliary transistor, respectively.

11. The power amplifier according to claim 1, wherein the output circuit comprises:
an output terminal;
a first output matching network transmission line and a second output matching network transmission line coupled to the two output harmonic control circuits, respectively;
a first matching capacitor, with a terminal of the first matching capacitor coupled to the first output matching network transmission line, and another terminal of the first matching capacitor grounded;
a second matching capacitor, with a terminal of the second matching capacitor coupled to the second output matching network transmission line, and another terminal of the second matching capacitor grounded;
a first transmission line, with a terminal of the first transmission line coupled to the first matching capacitor and the first output matching network transmission line;
a second transmission line, a terminal of the second transmission line coupled to the second matching capacitor and the second output matching network transmission line, and another terminal of the second transmission line coupled to the output terminal and another terminal of the first transmission line; and
a third transmission line, with a terminal of the third transmission line coupled to another terminal of the first transmission line and another terminal of the second transmission line, and another terminal of the third transmission line grounded and acting as a feed-in terminal for a drain direct current supply voltage of the main transistor and the auxiliary transistor.

12. The power amplifier according to claim 11, wherein a capacitance value of the first matching capacitor, a capacitance value of the second matching capacitor and an impedance and a phase of each of the first transmission line, the second transmission line and the third transmission line are obtained by performing an equivalent transformation on two matching inductors of two output matching networks of the output circuit and a single transmission line.

13. The power amplifier according to claim 12, wherein a total length of the first transmission line, the second transmission line and the third transmission line is smaller than a length of the single transmission line.

14. The power amplifier according to claim 12, wherein an occupied area of the first transmission line, the second transmission line and the third transmission line is smaller than an occupied area of the single transmission line.

15. The power amplifier according to claim 12, wherein the equivalent transformation comprises one or more π model equivalent circuit transformations.

16. The power amplifier according to claim 12, wherein the equivalent transformation comprises one or more wye-delta equivalent transformations.

17. The power amplifier according to claim 11, wherein the input circuit comprises:
an input terminal;
a power splitter coupled to the input terminal;
a phase shifter coupled to the power splitter; and
two input matching networks, with one of the two input matching networks coupled between the power splitter and one of the two input harmonic control circuits, and another one of the two input matching networks coupled between the phase shifter and another one of the two input harmonic control circuits.
